(19) United States
(12) Patent Application Publication
(10) Pub. No.: US 2025/0294940 A1
(43) Pub. Date: Sep. 18, 2025

(54) DISPLAY APPARATUS

(71) Applicant: SAMSUNG ELECTRONICS CO., LTD., Suwon-si (KR)

(72) Inventors: Sunwoon Kim, Suwon-si (KR); Jongho Lee, Suwon-si (KR); Youngkyu Sung, Suwon-si (KR); Donggyu Shin, Suwon-si (KR)

(21) Appl. No.: 18/890,462

(22) Filed: Sep. 19, 2024

(30) Foreign Application Priority Data
Mar. 18, 2024 (KR) 10-2024-0036885

(51) Int. Cl. H01L 27/15; H01L 25/065

(52) U.S. Cl. CPC H10H 29/142; H01L 25/0657

(57) ABSTRACT

A display apparatus includes a circuit board including a driving circuit; a pixel array disposed on the circuit board and in which a plurality of LED cells respectively including a first conductivity-type semiconductor layer, an active layer, and a second conductivity-type semiconductor layer sequentially stacked are arranged; and microlenses arranged on the plurality of LED cells, in which the pixel array includes: a reflective layer; a passivation layer; and bonding electrodes passing through the passivation layer, and in which the reflective layer is configured to transmit light having an incidence angle equal to or less than a first angle among light incident on the first surface, and to reflect light having an incidence angle of a second angle that is greater than the first angle.

### CROSS-REFERENCE TO RELATED APPLICATION(S)

This application claims benefit of priority to Korean Patent Application No. 10-2024-0036885 filed on Mar. 18, 2024, in the Korean Intellectual Property Office, the disclosure of which is incorporated herein by reference in its entirety.

### BACKGROUND

A semiconductor light-emitting diode (LED) is used not only as a light source for a lighting device, but also as a light source for various electronic products. Specifically, the LED is widely used as a light source for various types of display apparatus such as TVs, mobile phones, PCs, laptop PCs, and PDAs.

A display apparatus is mainly comprised of a display panel formed of a liquid crystal display (LCD) and a backlight, and has recently been developed in a form that uses an LED as a pixel and does not require a separate backlight. Such a display apparatus may not only be miniaturized, but also may implement a high-brightness display apparatus having light efficiency superior to the LCD.

### SUMMARY

In general, in some aspects, the present disclosure is directed toward a display apparatus having improved light extraction efficiency.

According to some implementations, the present disclosure is directed to a display apparatus that includes a circuit board including a driving circuit; a pixel array disposed on the circuit board and in which a plurality of LED cells respectively including a first conductivity-type semiconductor layer, an active layer, and a second conductivity-type semiconductor layer sequentially stacked are arranged; and microlenses arranged on the plurality of LED cells, wherein the pixel array includes: a reflective layer disposed between the plurality of LED cells and the microlenses and having a first surface facing the plurality of LED cells and a second surface facing the microlenses; reflective electrodes extending to cover at least a side surface of each of the plurality of LED cells; a passivation layer between the plurality of LED cells and the reflective electrodes; and bonding electrodes passing through the passivation layer and configured to electrically connect the first conductivity-type semiconductor layer and the second conductivity-type semiconductor layer to the driving circuit, wherein the reflective layer is configured to transmit light having an incidence angle equal to or less than a first angle among light incident on the first surface, and to reflect light having an incidence angle of a second angle that is greater than the first angle.

According to some implementations, the present disclosure is directed to a display apparatus that includes a circuit board including a driving circuit; a pixel array disposed on the circuit board and in which a plurality of LED cells respectively including a first conductivity-type semiconductor layer, an active layer, and a second conductivity-type semiconductor layer sequentially stacked are arranged; and microlenses arranged on the plurality of LED cells, wherein the pixel array includes: a reflective layer between the plurality of LED cells and the microlenses; reflective electrodes extending to cover at least a side surface of each of the plurality of LED cells; a passivation layer between the plurality of LED cells and the reflective electrodes; and bonding electrodes passing through the passivation layer and configured to electrically connect the first conductivity-type semiconductor layer and the second conductivity-type semiconductor layer to the driving circuit, the plurality of LED cells include a first LED cell configured to emit light of a first wavelength, a second LED cell configured to emit light of a second wavelength, longer than the first wavelength, and a third LED cell configured to emit light of a third wavelength longer than the second wavelength, and the reflective layer transmits at least a portion of each of the light of a first wavelength, the light of a second wavelength, and the light of a third wavelength, wherein the light of the third wavelength is transmitted in a predetermined incidence angle and is reflected at an incidence angle greater than the predetermined incidence angle.

According to some implementations, the present disclosure is directed to a display apparatus that includes a circuit board including a driving circuit; a pixel array disposed on the circuit board and in which pixel units respectively formed of a plurality of subpixels are arranged; and microlenses aligned on the plurality of subpixels, wherein the pixel array includes: a plurality of LED cells respectively corresponding to the plurality of subpixels and respectively including a first conductivity-type semiconductor layer, an active layer, and a second conductivity-type semiconductor layer; a first conductive semiconductor base layer on the first conductive semiconductor layer of each of the plurality of LED cells; a reflective layer between the first conductive semiconductor base layer and the microlenses; reflective electrodes configured to cover a side surface and a lower surface of each of the plurality of LED cells; and bonding electrodes configured to electrically connect the first conductivity-type semiconductor base layer and the second conductivity-type semiconductor layer to the driving circuit, wherein the reflective layer is configured to transmit light having an incidence angle within a first angle, among light emitted from the plurality of LED cells, and reflect light having an incidence angle of a second angle greater than the first angle.

According to some implementations, the present disclosure is directed to a display apparatus having improved light extraction efficiency may be provided by introducing a reflective layer that transmits only a predetermined range of incident light.

### BRIEF DESCRIPTION OF DRAWINGS

Example implementations will be more clearly understood from the following detailed description, taken in conjunction with the accompanying drawings.

FIG. 1 is a schematic perspective view of an example of a display apparatus according to some implementations.

FIG. 2 is a partially enlarged view of an example area ‘A’ of FIG. 1 according to some implementations.

FIG. 3A is a schematic cross-sectional view of an example of a display apparatus according to some implementations, and FIG. 3B is a partially enlarged view illustrating an example area ‘B’ of FIG. 3A according to some implementations.

FIG. 4 is a schematic partial enlarged view of an example of a display apparatus according to some implementations.

FIGS. 5A to 5C are graphs illustrating examples light extraction efficiency of a display apparatus according to some implementations.

FIG. 6 illustrates an example of a driving circuit implemented in a display apparatus according to some implementations.

FIG. 7 is a schematic cross-sectional view of an example of a display apparatus according to some implementations.

FIGS. 8A and 8B are schematic cross-sectional views of examples of a display apparatus according to some implementations.

FIGS. 9A to 9I are cross-sectional views for each process illustrating an example of a method of manufacturing a display apparatus according to some implementations.

FIG. 10 is a diagram of an example of an electronic device to which a display apparatus is applied according to some implementations.

### DETAILED DESCRIPTION

Hereinafter, example implementations will be described in detail with reference to the accompanying drawings.

Hereinafter, example implementations of the present disclosure will be described with reference to the accompanying drawings. Unless otherwise specified, in the present specification, it may be understood that the expressions such as “on,” “above,” “upper,” “below,” “beneath,” “lower,” and “side,” merely indicated based on drawings, and may actually vary depending on the direction in which the components are disposed.

Furthermore, in order to distinguish various elements, operations and directions from each other, ordinal numbers such as “first,” “second,” “third,” etc. may be used as labels such as specific elements, steps, and directions, terms not described using “first,” “second,” etc. in the specification may still be referred to as “first” or “second” in the claim. In addition, terms referred to as specific ordinal numbers (e.g., “first” in certain claims) may be described as different ordinal numbers (e.g., “second” in specifications or other claims) elsewhere.

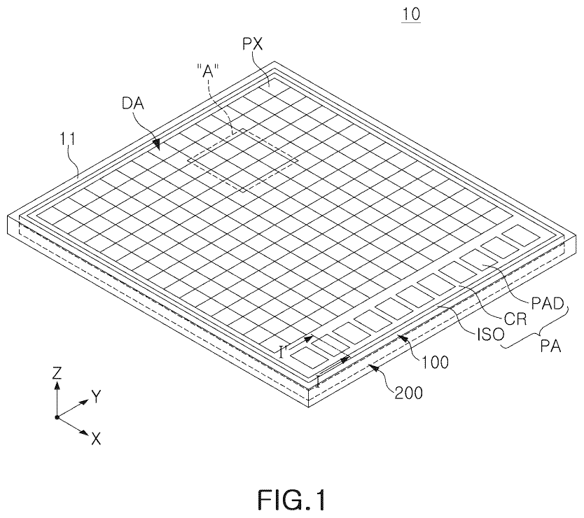

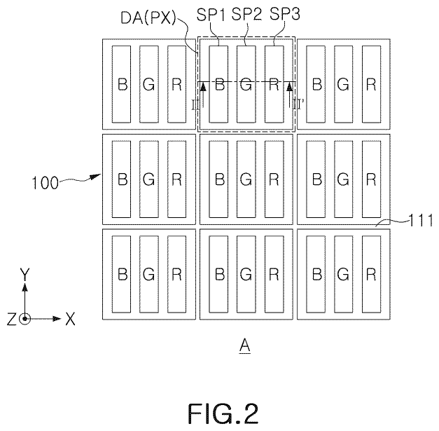

FIG. 1 is a schematic perspective view of an example of a display apparatus according to some implementations, and FIG. 2 is a partially enlarged view of an example area ‘A’ of FIG. 1 according to some implementations. In FIGS. 1 and 2, a display apparatus 10 includes a circuit board 200 including driving circuits and a pixel array 100, which is disposed on the circuit board 200 and in which a plurality of pixels PX are arranged. The display apparatus 10 may further include a frame 11 surrounding the circuit board 200 and the pixel array 100.

The circuit board 200 may include a driving circuit including thin film transistor (TFT) cells. In some implementations, the circuit board 200 may further include other circuits in addition to driving circuits for the display apparatus. In some implementations, the circuit board 200 may include a flexible board, and the display apparatus 10 may be implemented as a display apparatus having a curved profile.

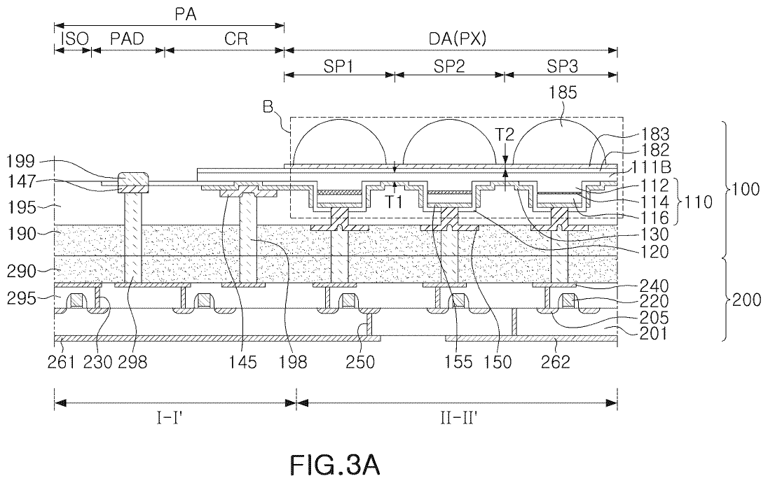

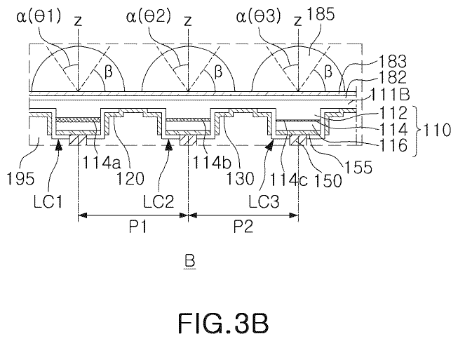

The pixel array 100 may include a display region DA and a peripheral region PA on at least one side of the display region DA. The display region DA may include a display LED module in which a plurality of pixels PX are arranged. Each of the plurality of pixels PX may include first to third subpixels SP1, SP2 and SP3 configured to emit light of a specific wavelength, for example, a specific color, in order to provide a color image. For example, the first to third subpixels SP1, SP2 and SP3 may be configured to emit blue (B) light, green (G) light, and red (R) light, respectively. According to some implementations, pixel array 100 may include an LED module or cell (see FIGS. 3A and 3B) configured to directly emit blue (B) light, green (G) light, and red (R) light without using an additional wavelength converter. In some implementations, the first to third subpixels SP1, SP2 and SP3 may all be configured to emit light of the same color. For example, the display apparatus may be a three-panel type display apparatus including three display panels configured to emit blue (B) light, green (G) light, and red (R) light, respectively.

In FIG. 1, the plurality of pixels PX are illustrated as being arranged in a 15×15 grid, but columns and columns may be implemented as any appropriate number, for example, 1,024×768. For example, depending on the desired resolution, the plurality of pixels PX may have different arrangements.

In FIG. 2, in each pixel PX (or pixel unit), the first to third subpixels SP1, SP2 and SP3 may have a pattern arranged side by side in one direction (e.g., X-direction). The present disclosure is not limited thereto, and in some implementations, the first to third subpixels SP1, SP2 and SP3 may be arranged in another pattern, such as a Bayer pattern. According to some implementations, each of the pixels PX may be configured in a different arrangement such as 3×3 or 4×4.

The peripheral region PA may include pad regions PAD, a connection region CR connecting the plurality of pixels PX and the pad regions PAD, and an outer region ISO. The pad regions PAD may be disposed on at least one side of the plurality of pixels PX along an edge of the display apparatus 10. The pad regions PAD may be electrically connected to the plurality of pixels PX and driving circuits of the circuit board 200. The pad regions PAD may electrically connect the display apparatus 10 to an external device. In some implementations, the number of pad regions PAD may be variously changed, but may be determined depending on, for example, the number of pixels PX, a driving method of a TFT circuit in the circuit board 200, and the like.

The connection region CR may be an area disposed between the plurality of pixels PX and the pad regions PAD. A wiring structure, such as a common electrode, which is electrically connected to the plurality of pixels PX, may be disposed in the connection region CR. The outer region ISO may be a region along the edges of the pixel array 100. The outer region ISO may be a region in which an upper semiconductor layer 111B (or ‘first conductive semiconductor base layer’) is not disposed (see FIG. 3A).

The frame 11 may be disposed around the pixel array 100 and may serve as a guide for defining an arrangement space of the pixel array 100. The frame 11 may include, for example, at least one of materials such as polymer, ceramic, semiconductor, or metal. For example, the frame 11 may include a black matrix. However, the frame 11 is not limited to the black matrix, and may include a white matrix or a structure of another color depending on the purpose of the display apparatus 10. For example, the white matrix may include a reflective material or a light scattering material. The display apparatus 10 in FIG. 1 is illustrated as having a rectangular planar structure, but may have a different shape according to some implementations.

FIG. 3A is a schematic cross-sectional view of the display apparatus 10 according to some implementations, and FIG. 3B is a partially enlarged view illustrating an example area ‘B’ of FIG. 3A according to some implementations. FIG. 3A may be understood as a combination of a cross-section taken along line I-I′ of FIG. 1 (peripheral region PA) and a cross-section taken along II-II′ of FIG. 2 (display region DA).

In FIGS. 3A and 3B, a display apparatus 10 includes a circuit board 200 and a pixel array 100 disposed on the circuit board 200. The circuit board 200 may include a semiconductor substrate 201, a driving circuit including driving elements 220 including TFT cells formed on the semiconductor substrate 201, interconnection portions 230 electrically connected to the driving elements 220, wiring layers 240 on interconnection portions 230, and a circuit insulation layer 295 covering the driving circuit. The circuit board 200 may further include a first bonding insulating layer 290 on the circuit insulating layer 295, and first bonding electrodes 298 disposed in the first bonding insulating layer 290 and connected to the wiring layers 240.

The semiconductor substrate 201 may include impurity regions including source/drain regions 205. The semiconductor substrate 201 may include, for example, a semiconductor such as silicon (Si) or germanium (Ge), or a compound semiconductor such as SiGe, SiC, GaAs, InAs, or InP. The semiconductor substrate 201 may further include through-electrodes 250 such as a through-silicon via (TSV) connected to the driving circuit, and first and second substrate wiring lines 261 and 262 connected to the through-electrodes 250.

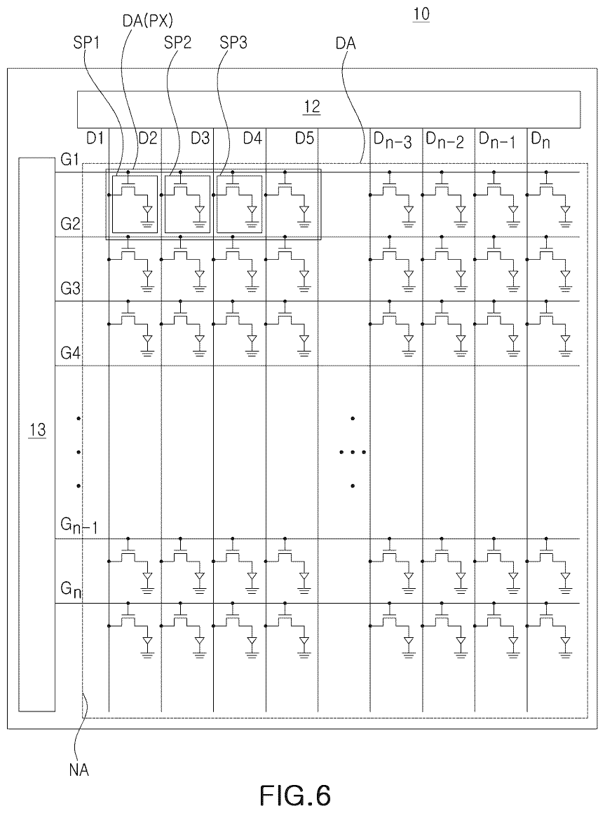

The driving circuit may include a circuit for controlling driving of a pixel, particularly a subpixel. The source region 205 of the TFT cells may be electrically connected to an electrode at one side of the LED cells 110 through the interconnection portion 230, the wiring line 240, and the first bonding electrode 298. For example, the drain region 205 of the TFT cells may be connected to a first wiring line 261 through the through-electrode 250, and the first wiring line 261 may be connected to a data line. Gate electrodes of the TFT cells may be connected to a second wiring line 262 through the through-electrode 250, and the second wiring line 262 may be connected to a gate line. This circuit configuration and operation will be described in more detail with reference to FIG. 6 below.

Upper surfaces of the first bonding electrodes 298 and upper surfaces of the first bonding insulating layer 290 may be included in an upper surface of the circuit board 200. The first bonding electrodes 298 may be bonded to the second bonding electrodes 198 of the pixel array 100, and may provide an electrical connection path. The first bonding electrodes 298 may include a conductive material, for example, copper (Cu). The first bonding insulating layer 290 may be bonded to the second bonding insulating layer 190 of the pixel array 100. The first bonding insulating layer 290 may include, for example, at least one of silicon oxide (SiO), silicon nitride (SiN), silicon carbonitride (SiCN), silicon oxycarbide (SiOC), silicon oxynitride (SiON), and silicon oxycarbonitride (SiOCN).

The pixel array 100 may include LED cells 110, a passivation layer 120 covering side surfaces of the LED cells 110, reflective electrodes 130 and 150 surrounding at least a portion of each of the LED cells 110, and a reflective layer 183 between the microlenses 185 and the LED cells 110.

The microlenses 185 may be disposed on the reflective layer 183. The microlenses 185 are arranged to correspond to first to third subpixels SP1, SP2 and SP3, and may focus light transmitted through the reflective layer 183. For example, the microlenses 185 may have a diameter larger than a width of the LED cells 110 in an X-direction and a Y-direction. The microlenses 185 may be formed of, for example, a transparent photoresist material or a transparent thermosetting resin film. According to some implementations, an upper passivation layer 182 may be disposed between the reflective layer 183 and the first conductive semiconductor base layer 111B. The upper passivation layer 182 may include an insulating material, for example, at least one of SiO₂, SIN, SiCN, SiOC, SiON, SiOCN, SiOCN, HfOₓ, AlOₓ, ZrOₓ, and AlN.

The pixel array 100 may further include a first conductive semiconductor base layer 111B on the LED cells 110, contact layers 155 on lower surfaces of the LED cells 110, a common electrode 145, a first pad electrode 147, a wiring insulating layer 195, a second bonding insulating layer 190, second bonding electrodes 198, and a second pad electrode 199.

The LED cells 110 may be included in each of the first to third subpixels SP1, SP2 and SP3, and may be included in each of micro LEDs. A width of each of the LED cells 110 may be approximately 10 μm or less. The LED cells 110 may be arranged in columns and rows. In some implementations, each of the LED cells 110 may include a first conductive semiconductor layer 112, an active layer 114, and a second conductive semiconductor layer 116, which are sequentially stacked below the first conductive semiconductor base layer 111B. Additionally, the LED cells 110 may include first to third LED cells LC1, LC2 and LC3 respectively configured to emit light of different wavelengths.

The first conductive semiconductor base layer 111B may be provided as a common layer shared by the LED cells 110 (e.g., the first to third LED cells LC1, LC2 and LC3) of all pixels PX. A thickness T1 of the first conductive semiconductor base layer 111B may be, for example, approximately 300 nm or more, for example, in the range of approximately 300 m to approximately 1 μm, but the present disclosure is not limited thereto. The first conductive semiconductor base layer 111B may be arranged to extend from a display region DA to a connection region CR and pad regions PAD, that is, a portion of the peripheral region PA. The first conductive semiconductor base layer 111B may be provided as a region for forming a common electrode for all or a portion of the first to third LED cells LC1, LC2 and LC3 (e.g., the same row or column).

The first conductive semiconductor layer 112, the active layer 114, and the second conductive semiconductor layer 116 may be formed of a nitride semiconductor, but may be an epitaxial layer. The first conductive semiconductor layer 112 and the second conductive semiconductor layer 116 may be a nitride semiconductor layer having a composition of N-type and P-type InₓAl_{y}Ga_{1-x-y}N (0≤x<1, 0≤y<1, 0≤x+y<1). The first conductive semiconductor base layer 111B may be a nitride semiconductor layer having a composition N-type InₓAl_{y}Ga1_{-x-y}N (0≤x<1, 0≤y<1, 0≤x+y<1) which is identical to that of the first conductive semiconductor layer 112. For example, the first conductive semiconductor layer 112 may be an N-type gallium nitride (n-GaN) layer doped with silicon (Si), germanium (Ge), or carbon (C), and the second conductive semiconductor layer 116 may be a P-type gallium nitride (p-GaN) layer doped with magnesium (Mg) or zinc (Zn). However, according to some implementations, the first conductive semiconductor layer 112 and the second conductive semiconductor layer 116 may be formed of a semiconductor layer of aluminum indium gallium phosphide (AlInGaP) or aluminum indium gallium arsenide (AlInGaAs) series, in addition to the nitride semiconductor. Each of the first conductive semiconductor layer 112 and the second conductive semiconductor layer 116 may be formed as a single layer, but may include a plurality of layers having different characteristics such as doping concentration and composition.

The active layer 114 may emit light having a predetermined energy by recombination of electrons and holes. The active layer 114 may have a single (SQW) or multiple quantum well (MQW) structure in which quantum barrier layers and quantum well layers are alternately arranged. For example, the quantum well layer and the quantum barrier layer may be InₓAl_{y}Ga_{1-x-y}N (0≤x≤1, 0≤y≤1, 0≤x+y≤1) layers having different compositions. For example, the quantum well layer is an InₓGa₁₋ₓN (0<x≤1), and the quantum barrier layer may be a GaN layer or an AlGaN layer.

In some implementations, the first to third LED cells LC1, LC2 and LC3 may include first to third active layers 114a, 114b and 114c configured to emit light of different wavelengths, respectively. Since the first to third active layers 114a, 114b and 114c are formed simultaneously through the same growth process, the first to third active layers 114a, 114b and 114c may also include layers corresponding to each other. For example, the first to third active layers 114a, 114b and 114c may include the same number of quantum barrier layers and quantum well layers (see FIG. 3B).

The first active layer 114a may include a first quantum well layer configured to emit blue light, for example, light having a wavelength of 440 nm to 480 nm. The second active layer 114b may include a second quantum well layer configured to emit green light, for example, light having a wavelength of 510 nm to 550 nm. Additionally, the third active layer 114c may include a third quantum well layer configured to emit red light, for example, light having a wavelength of 610 nm to 650 nm.

The first to third quantum well layers may include InₓGa₁₋ₓN (0<x≤1) layers having different indium contents (x). For example, the indium content of the first quantum well layer may range from 0.15 to 0.2, the indium content of the second quantum well layer may range from 0.25to 0.3, and the indium content of the third quantum well layer may range from 0.3 to 0.35. For example, the quantum barrier layer may be GaN or AlGaN.

In some implementations, a thickness of the first active layer 114a is thicker than a thickness of the second active layer 114b, and the thickness of the second active layer 114b may be thicker than a thickness of the third active layer 114c. Specifically, a thickness of the first quantum well layer may be thicker than a thickness of the second quantum well layer, and the thickness of the second quantum well layer may be thicker than a thickness of the third quantum well layer. For example, the thickness of the first quantum well layer may range from 2.5 nm to 4 nm, the thickness of the second quantum well layer may range from 2.5 nm to 3.5 nm, and the thickness of the third quantum well layer may range from 2 nm to 3 nm.

The passivation layer 120 may extend below the second conductive semiconductor layers 116 of the LED cells 110 to cover a side surface of the LED cells 110. The passivation layer 120 may covers a portion of the lower surfaces and side surfaces of the LED cells 110, and may extend into the peripheral region PA. The passivation layer 120 may be disposed to cover a lower surface of the first conductive semiconductor layer 112 in the connection region CR and the pad regions PAD, that is, in the peripheral region PA. The passivation layer 120 may include at least one of an insulating material, for example, SiO₂, SiN, SiCN, SiOC, SiON, and SiOCN.

The first reflective electrode 130 may be disposed below the passivation layer 120 and may be electrically connected to the first conductive semiconductor layers 112 of the LED cells 110. Specifically, the first reflective electrode 130 may be spaced apart from the LED cell 110 by the passivation layer 120 on the side surfaces of the LED cell 110 and may extend to the outside of the LED cell 110. The externally extending first reflective electrode 130 may be connected in regions between adjacent LED cells 110 and may be arranged in a single layer. The first reflective electrode 130 may have a shape extending from one side surface of one LED cell 110 to a side surface opposing the adjacent LED cell 110. For example, the first reflective electrode 130 may be arranged in an inverted U shape between the adjacent LED cells 110.

The first reflective electrode 130 may be electrically connected to the first conductive semiconductor layer 112 in the region between the LED cells 110. For example, the first reflective electrode 130 may penetrate through the passivation layer 120, and may electrically connect the first conductive semiconductor base layer 111B and the second bonding electrode 198. The first reflective electrode 130 may be disposed in a Z-direction so as not to overlap the LED cells 110, especially, the active layer 114 and the second conductive semiconductor layer 116, but the present disclosure is not limited thereto. The first reflective electrode 130 may extends from an outermost portion of the pixels PX to the connection region CR, may be connected to the first conductive semiconductor layer 112, and may be physically and electrically connected to the common electrode 145. Lines included in the first reflective electrode 130 may be connected to the common electrode 145 in ends thereof.

The first reflective electrode 130 may be formed of a metal, for example, at least one of silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and gold (Au). According to example embodiments, the first reflective electrode 130 may have a single layer structure or a multilayer structure of a conductive material.

The contact layers 155 and the second reflective electrodes 150 (or ‘lower reflective electrode’) may be sequentially disposed on lower surfaces of the second conductive semiconductor layers 116 and may be connected to the second conductive semiconductor layers 116. For example, a contact layer 155 may be disposed to cover an entire lower surface of the second conductive semiconductor layer 116. The second reflective electrode 150 may be arranged below each of the LED cells 110 to overlap the LED cells 110 in the Z-direction. The second reflective electrode 150 may be disposed between the LED cells 110 and the second bonding electrodes 198. The second reflective electrode 150 may be disposed below the contact layer 155 and may be connected to the contact layer 155. A length of the second reflective electrode 150 in the X-direction may be the same or similar to a length of the LED cells 110, but the present disclosure is not limited thereto, and the length thereof may vary in example embodiments. The second reflective electrode 150 may penetrate through the passivation layer 120, and may electrically connect the second bonding electrode 198 and the second conductive semiconductor layer 116. According to some implementations, the second reflective electrodes 150 may be omitted, and in this case, the contact layers 155 may be directly connected to the first bonding electrodes 198 below.

The contact layers 155 and the second reflective electrodes 150 may include, for example, a highly reflective metal, and may include, for example, at least one of silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and gold (Au).

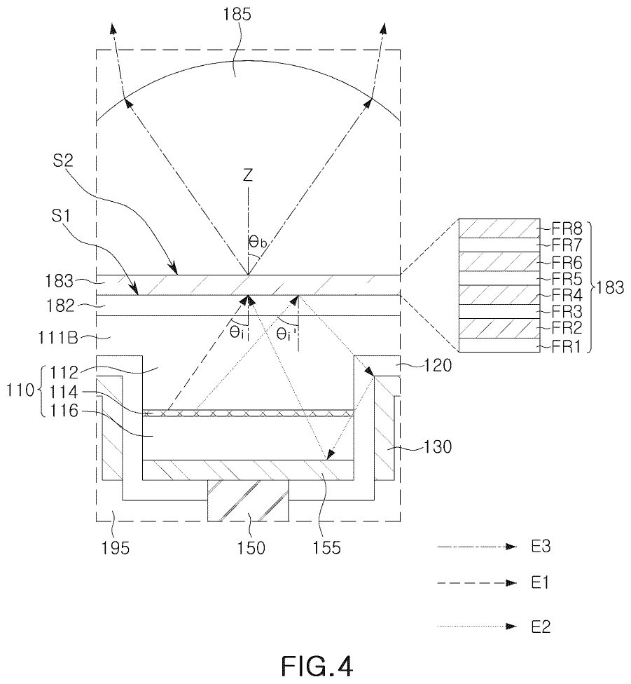

The reflective layer 183 may be disposed on the first conductive semiconductor layers 112 of the LED cells 110. According to some implementations, the reflective layer 183 may extend in a horizontal direction to cover all of the LED cells 110. The reflective layer 183 may be a Distributed Bragg Reflector (DBR) layer. The reflective layer 183 may include two or more refractive films having different refractive indices (see FIG. 4). The reflective layer 183 may use difference in transmittance of light emitted from the LED cells 110 to relatively increase the intensity of light emitted from a specific region.

For example, in FIG. 3B, the intensity of light transmitted through the reflective layer 183 may be greater than a second region (β) around a first region (α) in a first region (α) around a central axis (or ‘baseline’) (z), perpendicular to an upper surface of the reflective layer 183. The first region (α) may be defined as a region from the central axis (z) to rotation angles (θ1, θ2 and θ3) ranging from approximately 15° to approximately 30°, approximately 15° to approximately 25°, or approximately 15° to approximately 20° (0≤α≤θ1, θ2, θ3), and the second region (β) may be defined as a region from an edge of the first region (α) to an upper surface of the reflective layer 183 (a region from the central axis (z) to a rotation angle of 90°) (θ1, θ2, θ3<β≤90°).

According to some implementations, a first LED cell (LC1), a second LED cell (LC2), and a third LED cell (LC3) may be configured to emit light of different wavelengths. In this case, a first rotation angle (θ1) defining the first region (α) on the first LED cell (LC1), a second rotation angle (θ2) defining the first region (α) on the second LED cell (LC2), and a third rotation angle (θ3) defining the first region (α) on the third LED cell (LC3) may be different from each other.

A thickness T2 of the reflective layer 183 may be thinner than pitches P1 and P2 between the first to third LED cells (LC1, LC2 and LC3) included in each pixel PX. The first to third LED cells (LC1, LC2 and LC3) may be arranged with the same pitch (P1=P2). Here, the pitch may be defined as a distance between centers of adjacent LED cells. In the first to third LED cells (LC1, LC2 and LC3), each of pitches P1 and P2 may range from approximately 10 μm or less, for example, from approximately 0.1 μm to approximately 10 μm, from approximately 0.1 μm to approximately 5 μm, or from approximately 0.1 μm to approximately 1.0 μm, but the present disclosure is not limited thereto.

The reflective layer 183 may be configured to transmit only light within a predetermined incidence angle. That is, light having an incidence angle greater than a predetermined angle may be repeatedly reflected by the reflective layer 183 and the reflective electrodes 130 and 150, and may then re-enter the reflective layer 183 to transmit through the reflective layer 183 when a predetermined incidence angle condition is satisfied. Accordingly, in some implementations, the reflective layer 183 may improve a light extraction efficiency of the LED cells 110, thereby controlling a viewing angle shape. The reflective layer 183 may be a structure in which two or more layers of refractive films having different refractive indices are stacked. For example, the reflective layer 183 may include a plurality of refractive films stacked in 2 to 30 layers, and each of the plurality of refractive films may have a thickness ranging from approximately 10 nm to approximately 500 nm. This will be described in more detail with reference to FIG. 4.

The common electrode 145 and the first pad electrode 147 may be disposed in the connection region CR and the connection pad PAD, respectively. The common electrode 145 may be disposed on a lower surface of the first reflective electrode 130 extending from the pixel PX, and may connect the first reflective electrode 130 to the second bonding electrode 198. The common electrode 145 may form a common electrode structure together with the first reflective electrode 130. The common electrode 145 may be arranged in a square ring shape or a ring shape to surround the entire pixels PX in plan view, and may be connected to ends of the first reflective electrode 130. However, an arrangement shape of the common electrode 145 is not limited thereto, and may be variously changed in some implementations. The first pad electrode 147 may be disposed below the second pad electrode 199 in the connection pad PAD, thus connecting the second pad electrode 199 and the second bonding electrode 198. The common electrode 145 and the first pad electrode 147 may be formed of a conductive material, for example, at least one of silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and gold (Au).

The second pad electrode 199 may be disposed on the first pad electrode 147 in the connection pad PAD. The second pad electrode 199 may be arranged so that at least an upper surface thereof is exposed. The second pad electrode 199 may be connected to an external device, for example, to an external circuit (External IC) that may apply an electrical signal to the circuit board 200 by wire bonding or anisotropic conductive film (AFC) bonding. The second pad electrode 199 may electrically connect the driving circuits of the circuit board 200 and the external device. The second pad electrode 199 may include a metal, such as gold (Au), silver (Ag), or nickel (Ni).

The second bonding electrodes 198 may connect the second reflective electrodes 150, the common electrode 145, and the first pad electrode 147 to the first bonding electrodes 298 of the circuit board 200. The second bonding electrodes 198 may be connected to the second reflective electrodes 150 below the second reflective electrodes 150 in the pixel PX, may be connected to the common electrode 145 in the connection region CR, and may be connected to the first pad electrode 147 in the connection pad PAD. Among the second bonding electrodes 198, a height of the second bonding electrodes 198 connected to the second reflective electrodes 150 may be smaller than a height of the second bonding electrodes 198 connected to the common electrode 145 and the first pad electrode 147. The first reflective electrode 130 may be connected to the second bonding electrodes 198 through the common electrode 145, and the second reflective electrodes 150 may be directly connected to the second bonding electrodes 198. According to some implementations, an electrode pad partially buried in the first conductive semiconductor base layer 111B, and in contact with the first reflective electrode 130 may be further formed.

The second bonding electrodes 198 may be disposed to penetrate through the wiring insulating layer 195 and/or the second bonding insulating layer 190. The second bonding electrodes 198 may have a pillar shape, such as a cylinder. According to some implementations, the second bonding electrodes 198 may have a sidewall inclined so that an upper surface thereof is smaller than a lower surface thereof. The second bonding electrodes 198 may include copper (Cu), for example. The second bonding electrodes 198 may further include a barrier metal layer, for example, a tantalum (Ta) layer and/or a tantalum nitride (TaN) layer on an upper surface and side surfaces thereof.

The wiring insulating layer 195 may be disposed below the LED cells 110 together with the second bonding insulating layer 190. The wiring insulation layer 195 may include silicon oxide or a silicon oxide-based insulating material, and may be, for example, TetraEthyl Ortho Silicate (TEOS), Undoped Silicate Glass (USG), PhosphoSilicate Glass (PSG), Borosilicate Glass (BSG), BoroPhosphoSilicate Glass (BPSG), Fluoride Silicate Glass (FSG), Spin On Glass (SOG), Tonen SilaZene (TOSZ), or a combination thereof.

Lower surfaces of the second bonding insulating layer 190 may be arranged to form a lower surface of the pixel array 100 together with lower surfaces of the second bonding electrodes 198. The second bonding insulating layer 190 may form dielectric-dielectric bonding with the first bonding insulating layer 290. The circuit board 200 and the pixel array 100 may be bonded by bonding the first bonding electrodes 298 and the second bonding electrodes 198 and bonding the first bonding insulating layer 290 and the second bonding insulating layer 190. The bonding of the first bonding electrodes 298 and the second bonding electrodes 198 may be, for example, copper (Cu)-copper (Cu) bonding, and the bonding of the first bonding insulating layer 290 and the second bonding insulating layer 190 may be, for example, dielectric-dielectric bonding such as SiCN-SiCN bonding. The circuit board 200 and the pixel array 100 may be bonded by hybrid bonding including copper (Cu)-copper (Cu) bonding and dielectric-dielectric bonding, and may be bonded without a separate adhesive layer.

FIG. 4 is a schematic partial enlarged view of an example of a display apparatus according to some implementations. In FIG. 4, a path of light E1 and E2 is emitted from a single LED cell 110 to explain a light path by a reflective layer 183.

In FIG. 4, the reflective layer 183 may be configured to transmit the light E1 having an incidence angle in a first angle θᵢ among the light emitted from a plurality of LED cells 110, and reflect the light E2 having an incidence angle of a second angle θᵢ′ greater than the first angle θᵢ. Additionally, the reflective layer 183 may be configured so that transmitted light E3 has a predetermined refraction angle θ_{b} (or ‘a viewing angle’).

The light E1 incident on a first surface S1 at an angle (hereinafter referred to as ‘incidence angle condition’) that is equal to or smaller than the first angle θᵢ (e.g., at an incidence angle in the range of 0° to θᵢ) may be transmitted through the reflective layer 183 and may be emitted to a second surface S2. The first angle θᵢ may be approximately 40° or less, for example, approximately 40°, approximately 30°, approximately 20°, or approximately 15°, but the present disclosure is not limited thereto. In some implementations, the incidence angle condition for transmitting the first surface S1 of the reflective layer 183 may range from approximately 0° to approximately 40°, from approximately 0° to approximately 30°, or from approximately 0° to approximately 20°.

The light E3 transmitted through the reflective layer 183 may be transmitted through the second surface S2 at an angle equal to or smaller than a third angle θ_{b} (hereinafter referred to as ‘refraction angle condition’) (e.g., at a refraction angle in the range of 0° to θ_{b}). The third angle θ_{b} may be less than or equal to approximately 50°, for example, approximately 50°, approximately 40°, approximately 30°, approximately 20°, or approximately 10°, but the present disclosure is not limited thereto. In some implementations, the refraction angle condition of the light E3 transmitted through the second surface S2 may range from approximately 0° to approximately 50°, from approximately 0° to approximately 40°, from approximately 0° to approximately 30°, or from approximately 0° to approximately 20°, or from approximately 0° to approximately 10°.

A refraction angle of the light E3 transmitted through the reflective layer 183 may become smaller after passing through a corresponding microlens 185. For example, the refraction angle of the light E3 passing through the microlens 185 with respect to the second surface S2 may range from approximately 10° to approximately 30°, but the present disclosure is not limited thereto. Here, the refraction angle of the light E3 passing through the microlens 185 with respect to the second surface S2 may be understood as a viewing angle of the LED cell provided with a microlens. Here, the viewing angle may be defined as twice the angle at which a light output is 50% of a peak value.

The light E2 incident on the first surface S1 at the second angle θᵢ′ greater than the first angle θᵢ may be reflected by the reflective layer 183 and a reflective structure surrounding the LED cell 110 (e.g., the reflective electrode 130 and the contact layer 155) until the incidence angle condition is satisfied.

The incidence angle condition may be determined based on light of a specific wavelength (for example, light of a wavelength with relatively low light extraction efficiency). In some implementations, when the plurality of LED cells include a first LED cell configured to emit a wavelength of blue light, a second LED cell configured to emit green light, and a third LED cell configured to emit red light, the incidence angle condition may be set based on red light. For example, the reflective layer 183 may transmits at least a portion of each of the blue light, the green light, and the red light, but the reflective layer 183 may be configured to transmit the red light having a predetermined incidence angle and to reflect the red light having an incidence angle greater than the predetermined incidence angle. In some implementations, when the display apparatus is a 3 panel type, the incidence angle condition may be set based on the light emitted from each panel, for example, blue light, green light, or red light.

The reflective layer 183 may include two or more types of refractive films FR1, FR2, FR3, FR4, FR5, FR6, FR7 and FR8 with different refractive indices that are repeatedly stacked. The refractive films FR1, FR2, FR3, FR4, FR5, FR6, FR7 and FR8 may include, for example, at least one of silicon oxide, titanium oxide, aluminum oxide, zirconium oxide, and indium tin oxide. The refractive films FR1, FR2, FR3, FR4, FR5, FR6, FR7 and FR8 may be formed with different thicknesses. For example, the refractive films FR1, FR2, FR3, FR4, FR5, FR6, FR7 and FR8 may have a thickness ranging from approximately 50 nm to approximately 300 nm, but the present disclosure is not limited thereto. According to some implementations, the reflective layer 183 may include more or fewer refractive films than illustrated in the drawings.

In some implementations, the reflective layer 183 configured to have the incidence angle condition of approximately 15° for light with a wavelength of approximately 630 nm may include a first refractive film FR1 having a thickness of approximately 155 nm, a second refractive film FR2 having a thickness of approximately 251 nm, a third refractive film FR3 having a thickness of approximately 81 nm, a fourth refractive film FR4 having a thickness of approximately 168 nm, a fifth refractive film FR5 having a thickness of approximately 94 nm, a sixth refractive film FR6 having a thickness of approximately 169 nm, a seventh refractive film FR7 having a thickness of approximately 85 nm, and an eighth refractive film FR8 having a thickness of approximately 293 nm. The first, third, fifth and seventh refractive films FR1, FR3, FR5 and FR7 may include titanium dioxide (TiO₂), and the second, fourth, sixth and eighth refractive films FR2, FR4, FR6 and FR8 may include silicon dioxide (SiO₂).

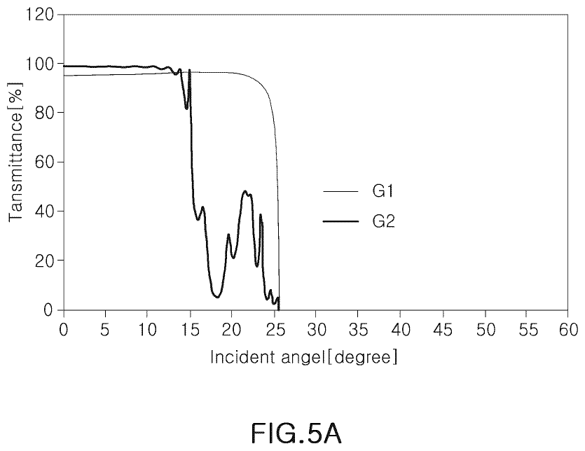

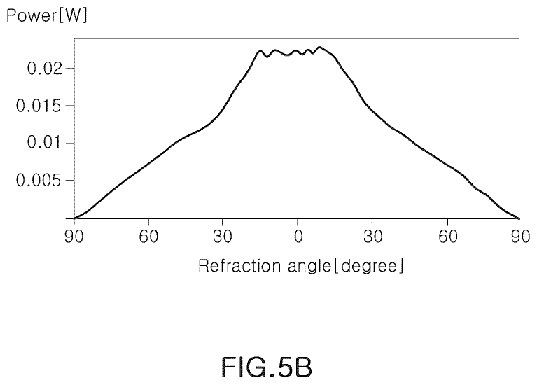

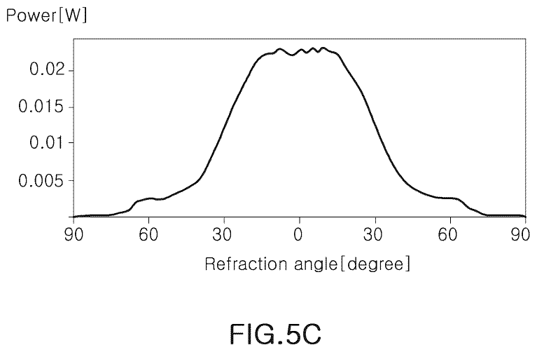

Hereinafter, referring to FIGS. 5A to 5C, a difference in light extraction efficiency between the LED cell 110 of FIG. 4 (hereinafter referred to as ‘LED cell of an implementation’) (radius of approximately 0.75 μm) including the reflective layer 183 in the above-described conditions, and a LED cell of a comparative example excluding the reflective layer 183 will be described.

FIGS. 5A to 5C are graphs illustrating examples of light extraction efficiency of a display apparatus according to some implementations. FIG. 5A is a result of simulating the transmittance according to an incidence angle of each LED cell of an implementation and an LED cell of a comparative example, FIG. 5B is a result of simulating a viewing angle shape of an LED cell of a comparative example, and FIG. 5C is a result of simulating a viewing angle shape of an LED cell of an implementations. FIGS. 5B and 5C illustrate a light output of LED cells of a comparative example and an implementation in the range of refraction angles from 0° to 90°.

In FIG. 5A, “G1” represents a change in transmittance according to the incidence angle of the LED cell of the comparative example, and “G2” represents a change in transmittance according to the incidence angle of the LED cell of the implementation. The LED cell of the comparative example transmits most of the light in an incidence angle of about 25°. On the other hand, the LED cell of the implementation transmits light in an incidence angle of about 15°, and light having an incidence angle of greater than about 15° has a sharp decrease in transmittance. The reflective layer 183 of an implementation reflects light that does not meet the designed incidence angle conditions, thereby improving a contrast ratio of the display and improving light efficiency.

In FIG. 5B, a viewing angle shape of the LED cell of the comparative example may be seen. Here, the viewing angle shape may be understood as a change in light output according to the refraction angle. In the case of the comparative example, the light extraction efficiency (LEE) is 5.07% in the range of the refraction angle from about 0° to about 90°, and the light extraction efficiency is 0.77% in the range of the refraction angle of about 0° to about 18.5°.

In FIG. 5C, the viewing angle shape of the LED cell of the implementation may be seen. In the implementation, in the range of the refraction angle from about 0° to about 90°, the light extraction efficiency decreased to 3.01% as compared to the LED cell of the comparative example, and in the range of the refraction angle from about 0° to about 18.5°, the light extraction efficiency, the light extraction efficiency increased to 0.8% in the range of the refraction angle from about 0° to about 18.5°. The decrease in the light extraction efficiency in the range of the refraction angle from about 0° to about 90° may be understood because light that does not meet the incidence angle condition of the reflective layer 183 is reflected.

As described above, according to some implementations, the viewing angle shape (or ‘a viewing angle’) of the LED cell may be concentrated in a required range, and the light extraction efficiency of the LED cell may be improved in a required refraction angle range (or a viewing angle range).

For example, when the LED cells with a diameter of about 0.6 μm are arranged at a pitch of about 2.7 μm, and a reflection structure and a microlens shape corresponding to each of the LED cells are optimized, the light extraction efficiency may range from about 35% to about 55% at a refraction angle of about 0° to about 90°, and the angle of refraction may be about 3% to about 10% at a refraction range of about 0° to about 18.5°. In addition, when applying the reflective layer 183 of an implementation, in a refraction angle ranging from about 0° to about 18.5°, the light extraction efficiency may be increased to about 3.1% to about 10.5% (about 5%). However, the present disclosure is not limited thereto, and depending on conditions, such as a size of the LED cell, a pitch between the LED cells, and a shape of the reflective structure, the light extraction efficiency may be increased by a large amount (about 10% or more) than described above.

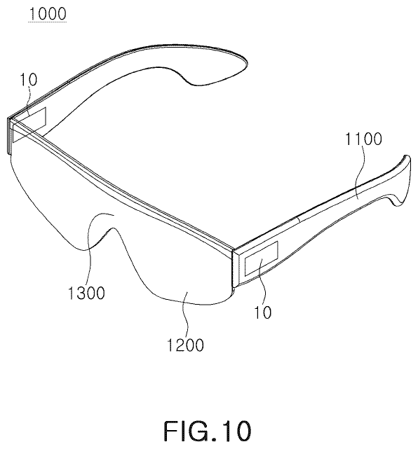

The display apparatus 10 according to some implementations may be more effectively applied to an electronic device (e.g., a wearable device) that requires a narrow viewing angle to generate high-resolution images (see FIG. 10). For example, in a device provided with a waveguide system configured to guide light emitted from the display apparatus, the light deviating from a required viewing angle may not pass through a waveguide and may be extinguished. According to some implementations, since the viewing angle of the display apparatus 10 (or the LED cell) decreases and the light output increases within the viewing angle, the light passing through the waveguide and contributing to image generation may be increased, thereby generating high-resolution images.

FIG. 6 illustrates an example of a driving circuit implemented in a display apparatus according to some implementations. In FIG. 6, a circuit diagram of a display apparatus 10 in which n×n subpixels are arranged is illustrated. Each of the first to third subpixels SP1, SP2 and SP3 may accommodate data signals through data lines D1 to Dn, which are paths in a vertical direction, for example, a row direction. The first to third subpixels SP1, SP2 and SP3 may accommodate receive control signals, that is, gate signals, through gate lines G1 to Gn, which are paths in a horizontal direction, for example, a column direction.

A plurality of pixels PX including the first to third subpixels SP1, SP2 and SP3 provide a display region DA, and the display region DA is an active region and is provided as a display region for a user. An inactive region NA (or a peripheral region PA) may be formed along one or more edges of the display region DA. The inactive region NA may extend along an outer periphery of a panel of the display apparatus 10.

The first and second driver circuits 12 and 13 may be employed to control an operation of the pixels PX, that is, first to third subpixels SP1, SP2 and SP3. Some or all of the first and second driver circuits 12 and 13 may be implemented on a circuit board 200. The first and second driver circuits 12 and 13 may be formed as integrated circuits, thin film transistor panel circuits, or other suitable circuits, and may be disposed in the nonactive region NA of the display apparatus 10. The first and second driver circuits 12 and 13 may include a microprocessor, a memory such as storage, a processing circuit, and a communication circuit.

In order to display an image by the pixels PX, the first driver circuit 12 may supply image data to the data lines D1 to Dn, and may simultaneously transmit clock signals and other control signals to the second driver circuit 13, which is a gate driver circuit. The second driver circuit 13 may be implemented using an integrated circuit and/or a thin film transistor circuit. A gate signal for controlling the first to third subpixels SP1, SP2 and SP3 arranged in the column direction may be transmitted through the gate lines G1 to Gn of the display apparatus 10.

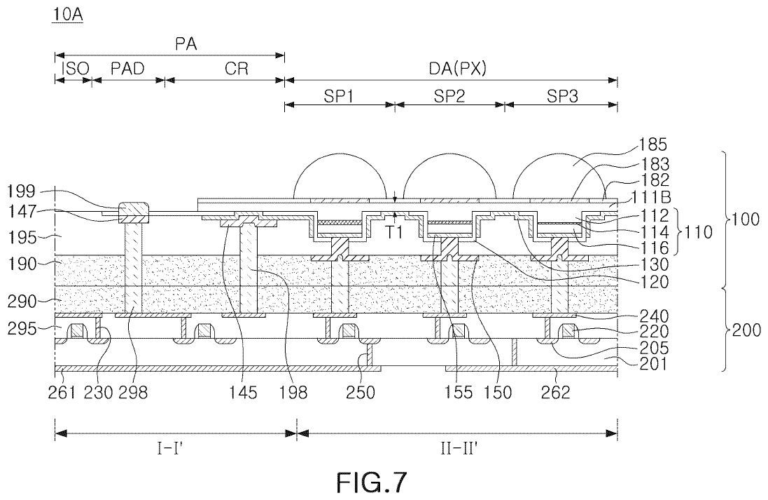

FIG. 7 is a schematic cross-sectional view of an example of a display apparatus according to some implementations. In FIG. 7, a display apparatus 10A may have the same or similar features as those described with reference to FIGS. 1 to 5C, except that a reflective layer 183 is buried in an upper passivation layer 182. The reflective layer 183 of an implementation may include LED cells 110 aligned vertically and a plurality of reflective layers 183 corresponding to microlenses 185. A plurality of reflective layers 183 may be disposed in a groove portion of a patterned upper passivation layer 182. Each of the plurality of reflective layers 183 may be configured to transmit only light that satisfies a predetermined incidence angle condition among the light emitted from LED cells 110 corresponding thereto. According to some implementations, the plurality of reflective layers 183 may be configured to have different materials, thicknesses, and incidence angle conditions.

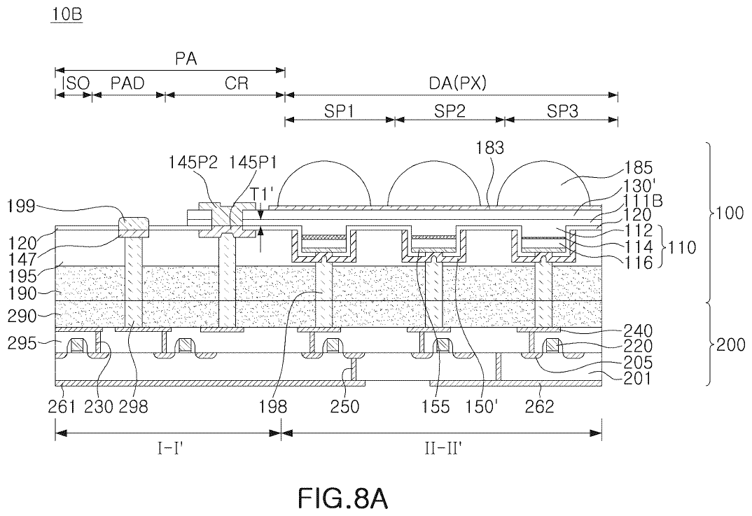

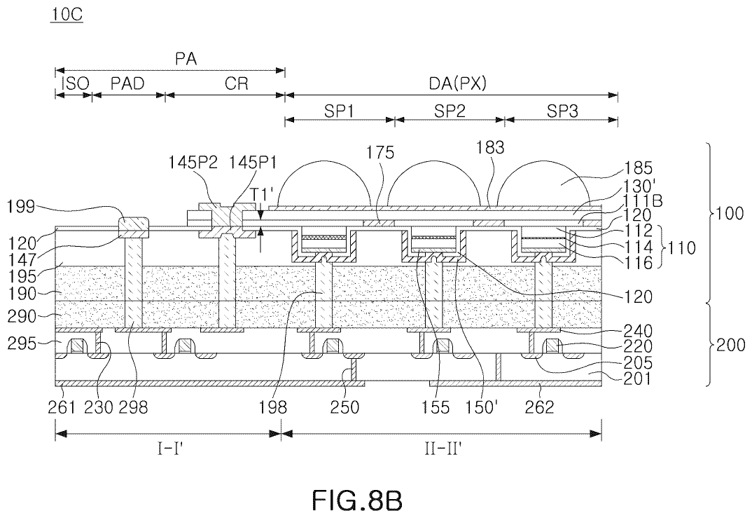

FIGS. 8A and 8B are schematic cross-sectional views of examples of a display apparatus according to some implementations. In FIG. 8A, a display apparatus 10B may be understood to be similar to the display apparatus 10 illustrated in FIGS. 3A and 3B, except that a transparent electrode layer 130′ is included as a common electrode of LED cells 110 on an upper surface of a first conductive semiconductor base layer 111B, and a reflection function is strengthened by forming a second reflective electrode (or ‘a lower reflective electrode’) 150′ in a bell-shaped structure. In addition, the components of some implementations may be understood by referring to the description of the same or similar components of the display apparatus 10 illustrated in FIGS. 1 to 3B, unless specifically stated to the contrary.

In some implementations, an under semiconductor layer is polished so that a partial region including a first conductivity-type semiconductor base layer 111B remains, and then, a transparent electrode layer 130 may be disposed on a polished surface of the remaining region. The remaining first conductive semiconductor base layer 111B may have a sufficiently thin thickness to prevent light leakage between subpixels. For example, a thickness T1′ of the remaining first conductive semiconductor base layer 111B may be 500 nm or less.

A transparent electrode layer 130′ may be formed on an upper surface (polished surface) of the remaining first conductive semiconductor base layer 111B. For example, the transparent electrode layer 130′ may include transparent conductive oxide (TCO) such as ITO, IZO, or GAZO. In an example embodiment, the transparent electrode layer 130′ may serve as a common electrode of the LED cell 110. The transparent electrode layer 130′ may extend to a peripheral region PA, that is, a connection region CR, which is disposed outside the pixels PX, and an extended portion of the transparent electrode layer 130′ may be connected to a second common electrode pad 145P2 on the other side by a first common electrode pad 145P1, and may be connected to a circuit board 200 through a first bonding electrode 198. The first common electrode pad 145P1 may penetrate through a passivation layer 120, and may electrically connect bonding electrodes 198 and the first conductive semiconductor base layer 111B.

The second reflective electrode 150′ employed in this example embodiment may have a vertical structure formed of a reflective electrode material. The second reflective electrode 150′ may have a bell-shaped structure surrounding an upper region and a side region of each of the LED cells 110 along a surface of the passivation layer 120. The second reflective electrode 150′ has a reflective structure and may improve the luminance of each of subpixel SP1, SP2 and SP3. In some implementations, a separate insulating film may be formed between the second reflective electrode 150′ and the passivation layer 120. The second reflective electrode 150′ may penetrate through the passivation layer 120, and may electrically connect the bonding electrodes 198 and the second conductive semiconductor layer 116 of each of the plurality of LED cells 110.

In FIG. 8B, a display apparatus 10C may be understood to be similar to the display apparatus 10B illustrated in FIG. 8A, except that the display apparatus 10C further includes a grid-shaped electrode layer together with the transparent electrode layer 130′. Additionally, the components of some implementations may be understood by referring to the description of the same or similar components of the display apparatus 10B illustrated in FIG. 8A, unless specifically stated to the contrary.

In some implementations, the under semiconductor layer is polished so that a partial region including the first conductivity-type semiconductor base layer 111B remains, and then, a transparent electrode layer 130′ may be disposed on a polished surface of the remaining region. In some implementations, a reflective electrode layer 175 may be introduced on a region overlapping a region between the LED cells 110 in the remaining first conductive semiconductor base layer 111B. From plan view, the overlapping region may have a grid shape, and the reflective electrode layer 175 may also have a grid shape. In some implementations, the reflective electrode layer 175 may be formed after removing at least a portion of the overlapping region of the remaining first conductive semiconductor base layer 111B, thereby more effectively preventing light leakage between subpixels.

Additionally, the reflective electrode layer 175 may be connected to the transparent electrode layer 130′ and may be used as a portion of the common electrode structure of the LED cell 110. As described above, in some implementations, the grid-shaped reflective electrode layer 175 may uniformly supply current to all subpixels in an entire area of the display. In some implementations, the reflective electrode layer 175 may extend to the peripheral region PA, that is, the connection region CR, which is disposed outside the pixels PX, and an extended portion of the reflective electrode layer 175 may be connected to the second common electrode pad 145P2 on the other side by the first common electrode pad 145P1, and may be connected to the circuit board 200 through the first bonding electrode 198.

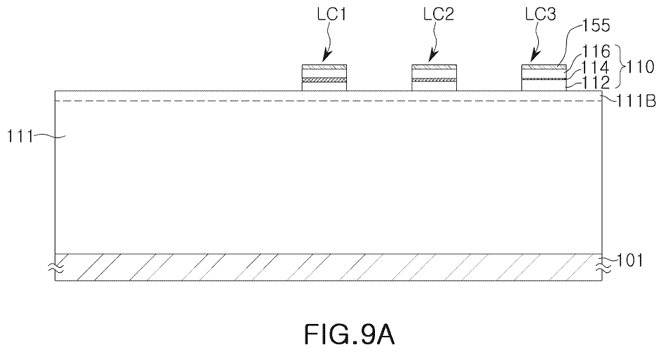

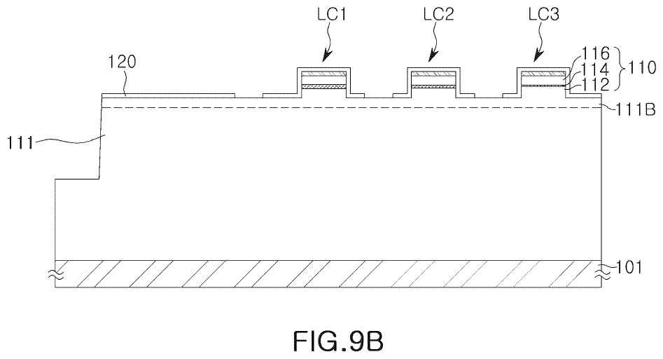

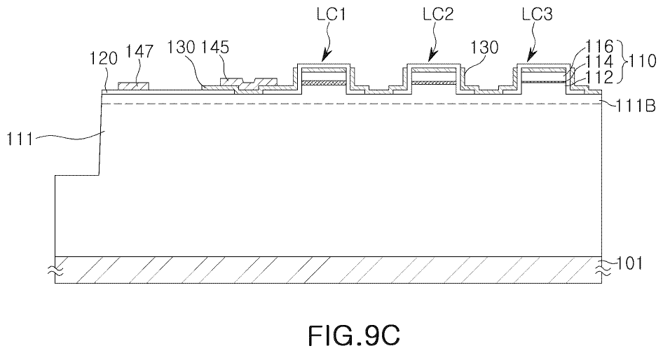

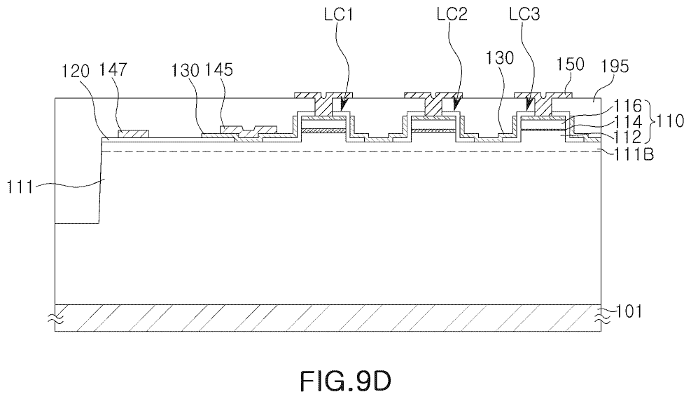

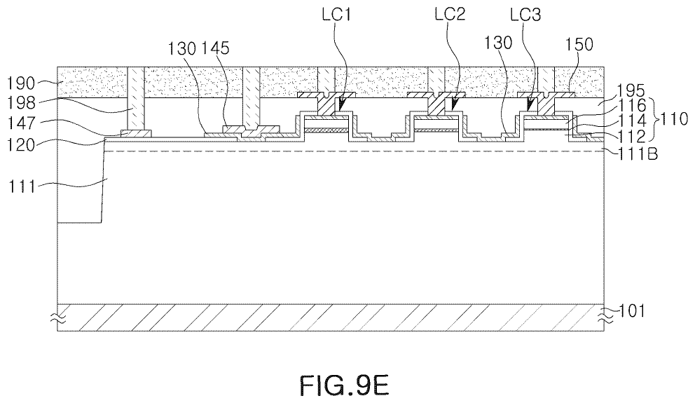

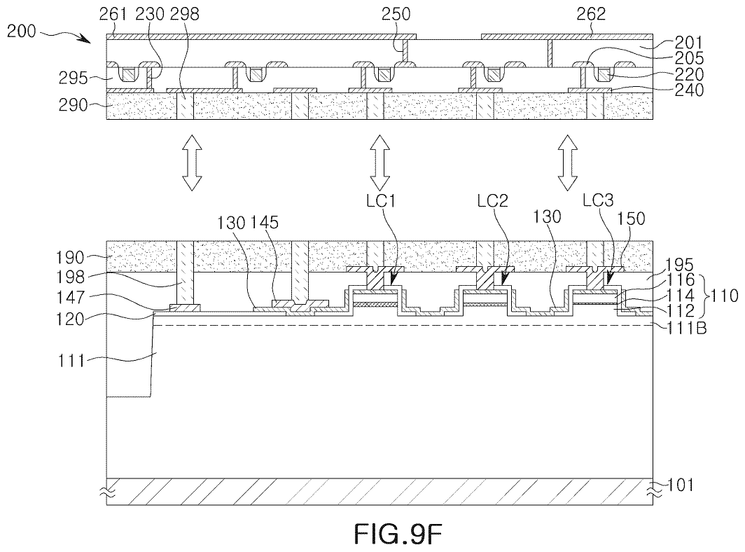

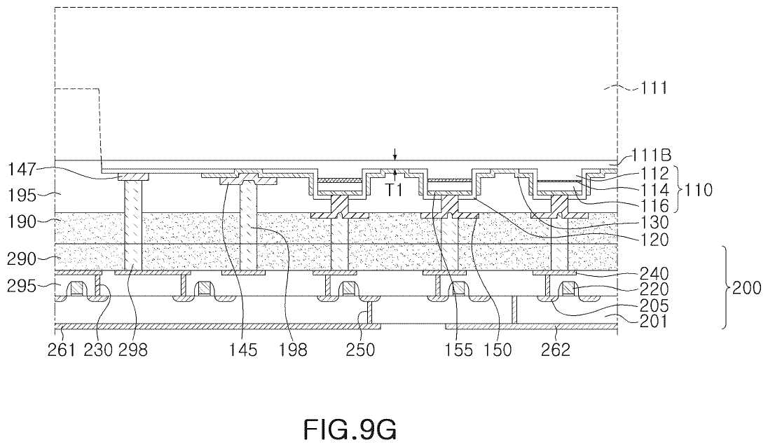

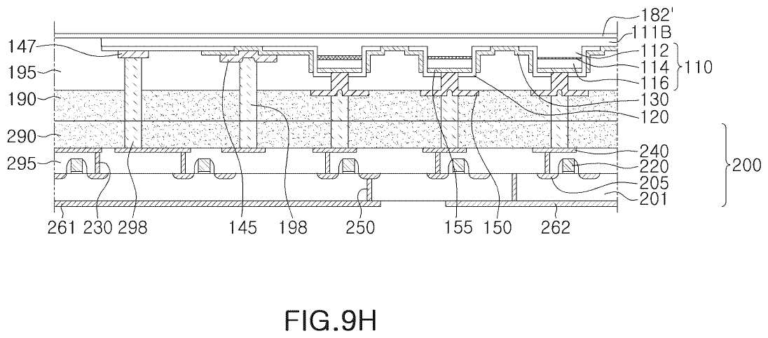

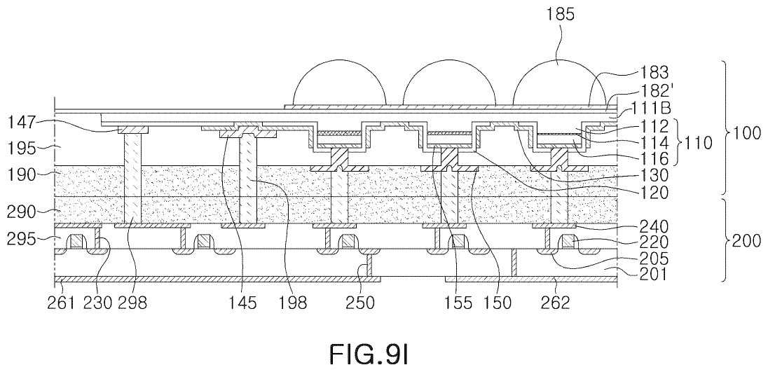

FIGS. 9A to 9I are cross-sectional views for each process illustrating an example of a method of manufacturing a display apparatus according to some implementations. In FIG. 9A, an upper semiconductor layer 111 (or ‘an under semiconductor layer’) having a first conductive semiconductor base layer 111B, a first conductivity-type semiconductor layer 112, an active layer 114, and a second conductivity-type semiconductor layer 116 may be sequentially on a growth substrate 101, and a contact layer 155 may be formed.

The growth substrate 101 may be for growing a nitride single crystal, and may include, for example, at least one of sapphire, Si, SiC, MgAl₂O₄, MgO, LiAlO₂, LiGaO₂, and GaN. In some implementations, in order to improve the crystallinity and light extraction efficiency of semiconductor layers, the growth substrate 101 may have a convex-convex structure on at least a portion of an upper surface thereof. In this case, the convex-convex portions may also be formed in layers grown on an upper portion thereof.

The upper semiconductor layer 111, the first conductive base semiconductor layer 111B, the active layer 114, and the second conductive semiconductor layer 116 may be formed using, for example, Metal Organic Chemical Vapor Deposition (MOCVD), Hydrogen Vapor Phase Epitaxy (HVPE), or Molecular Beam Epitaxy (MBE) processes.

The upper semiconductor layer 111 may include a first conductive semiconductor base layer 111B and a first conductive semiconductor layer or an undoped semiconductor layer thereunder. In some implementations, the upper semiconductor layer 111 may include a buffer layer and an undoped nitride layer (e.g., GaN). In this case, the buffer layer is for alleviating lattice defects of the first conductive semiconductor layer 112, and may include an undoped nitride semiconductor such as undoped GaN, undoped AlN, and undoped InGaN. The first conductive semiconductor base layer 111B and the first conductive semiconductor layer 112 may be an N-type nitride semiconductor layer such as N-type GaN, and the second conductive semiconductor layer 116 may be a P-type nitride semiconductor layer such as P-type GaN/P-type AlGaN. The active layer 114 may have a single quantum well or multiple quantum well structure such as InGaN/GaN. The contact layer 155 may be formed on the second conductive semiconductor layer 116. For example, the contact layer 155 may be a highly reflective ohmic contact layer.

In FIG. 9B, a passivation layer 120 may be formed on the first to third LED cells LC1, LC2 and LC3, and a portion of the upper semiconductor layer 111 may be removed from an outer region. The passivation layer 120 may be formed on an upper surface of the stack structure at a uniform thickness and may then be removed from some regions, that is, regions in which the first reflective electrode 130 (see FIG. 3A) is to be formed. For example, the passivation layer 120 may include at least one of SiO₂, SiN, SiCN, SiOC, SiON, and SiOCN. The passivation layer 120 may be formed conformally, and thus may have a substantially uniform thickness. Openings for the first reflective electrode 130 and the common electrode 145 to be formed in a subsequent process may be formed.

In the outer region (‘ISO’ in FIG. 3A), the upper semiconductor layer 111 may be removed to a predetermined depth. The outer region (ISO) is a region cut in the subsequent process and may be a region for separating modules. Accordingly, in order to prevent cracks from occurring during a cutting or dicing process, a portion of the upper semiconductor layer 111 may be removed in this operation.

In FIG. 9C, the first reflective electrode 130, the common electrode 145, and the first pad electrode 147 may be formed. Initially, the first reflective electrode 130 may be formed on the passivation layer 120 and the first conductive semiconductor layer 112. The first reflective electrode 130 may have a substantially uniform thickness. The first reflective electrode 130 may be formed in a region in which the pixels PX of FIG. 3A are disposed and the connection region CR.

Next, the common electrode 145 and the first pad electrode 147 may be formed in the connection region CR and the pad regions PAD of FIG. 3A, respectively. The common electrode 145 may be formed on the first reflective electrode 130 and the first pad electrode 147 may be formed on the passivation layer 120. The common electrode 145 and the first pad electrode 147 may be formed together through the same process. The first reflective electrode 130, the common electrode 145, and the first pad electrode 147 may include a conductive material, for example, a metal.

In FIG. 9D, a wiring insulating layer 195 may be formed, and second reflective electrodes 150 connected to the contact layers 155 may be formed. The wiring insulating layer 195 may include a first reflective electrode 130, and may be formed to cover all the structures formed in the previous operations, and then, a process of flattening the wiring insulating layer 195 may be performed using a flattening process, such as a chemical mechanical polishing (CMP) process or an etch-back process. For example, the wiring insulating layer 195 may be a low dielectric material such as silicon oxide.

Then, contact holes through which the contact layers 155 are exposed may be formed by penetrating through the wiring insulation layer 195 and the passivation layer 120, and second reflective electrodes 150 are formed by filling the contact holes with a conductive material. A portion of each of the second reflective electrodes 150 may extend to an upper surface of the wiring insulating layer 195.

In FIG. 9E, a bonding insulating layer 190 and bonding electrodes 198 may be formed on the second reflective electrodes 150. The bonding insulating layer 190 may include a material identical to or different from the wiring insulating layer 195. Additionally, the bonding insulating layer 190 may include a material different from that of the wiring insulating layer 195. The bonding electrodes 198 may be formed by forming via-holes penetrating through the bonding insulating layer 190 and the wiring insulating layer 195, and then filling the via-holes with a conductive material. The bonding electrodes 198 may be formed to be connected to the second reflective electrodes 150, the common electrode 145, and the first pad electrode 147.

In FIG. 9F, the circuit board 200 may be bonded to a pixel array structure including the first to third LED cells LC1, LC2 and LC3. The circuit board 200 may be prepared through a separate process. The pixel array structure and the circuit board 200 may be bonded on a wafer level by a wafer bonding method, such as hybrid bonding described above. The first bonding electrodes 298 may be bonded to the second bonding electrodes 198, and the first bonding insulating layer 290 may be bonded to the second bonding insulating layer 190. Accordingly, the structure including the LED cells 110 and the circuit board 200 may be bonded without a separate adhesive layer.

In FIG. 9G, the growth substrate 101 may be removed from the upper semiconductor layer 111 and a portion of the upper semiconductor layer 111 may be removed. In the drawings below, for better understanding, the structure including the LED cells 110 is illustrated in a bonded state in the form of a mirror image of the structure illustrated in FIG. 9F.

The growth substrate 101 may be removed by various processes, such as laser lift-off, mechanical polishing or mechanical chemical polishing, or an etching process.

For example, the upper semiconductor layer 111 may be partially removed to reduce a predetermined thickness using a polishing process such as CMP. For example, the upper semiconductor layer 111 may be removed to a level corresponding to a height of an upper surface of the first conductive semiconductor base layer 111B, and may be removed so that the upper semiconductor layer 111 does not remain in the edge region (ISO) (see FIG. 3A).

In FIG. 9H, a preliminary upper passivation layer 182′ may be formed on a pixel array structure including the LED cells 110. The preliminary upper passivation layer 182′ may be formed to cover the first conductive semiconductor base layer 111B and the wiring insulating layer 195. The preliminary upper passivation layer 182′ may include, for example, at least one of SiO₂, SiN, SiCN, SiOC, SiON, and SiOCN.

In FIG. 9I, a reflective layer 183 and microlenses 185 may be formed. The reflective layer 183 may be formed by alternately stacking two types of thin films with different refractive indices (see FIG. 4). The microlenses 185 may be formed to have a diameter larger than a horizontal width of the LED cells 110. The microlenses 185 may be formed of, for example, a transparent photoresist material or a transparent thermosetting resin film.

Then, the preliminary upper passivation layer 182′ and the first conductive semiconductor base layer 111B may be partially removed using an etching process. After partially removing the passivation layer 120 on the first pad electrode 147, the second pad electrode 199 may be formed and adjacent modules may be diced in the outer region (ISO), so that the display apparatus 10 of the example embodiment may be finally completed (see FIG. 3A).

FIG. 10 is a diagram of an example of an electronic device to which a display apparatus is applied according to some implementations. In FIG. 10, an electronic device 1000 may be a glasses-type display, which is a wearable device. The electronic device 1000 may include a pair of temples 1100, a pair of optical coupling lenses 1200, and a bridge 1300. The electronic device 1000 may further include a display apparatus 10 including an image generator.

The electronic device 1000 may be a head-mounted, glasses-type, or goggle-type virtual reality (VR) device which may provide virtual reality or provide both virtual images and actual external scenery, an augmented reality (AR) device, or a mixed reality (MR) device.

Temples 1100 may extend in one direction. The temples 1100 may be spaced apart from each other and extend in parallel. The temples 1100 may be folded toward a bridge 1300. The bridge 1300 may be provided between light coupling lenses 1200, and may connect the light coupling lenses 1200 together. The light coupling lenses 1200 may include a light guide plate. The display apparatus 10 may be disposed on each of the temples 1100 and may generate images on the light coupling lenses 1200. The display apparatus 10 may be a display apparatus according to the embodiments described above with reference to FIGS. 1 to 8B.

Among the lights emitted from the display apparatus 10, light in a predetermined viewing angle (e.g., 40°) may reach the light coupling lenses 1200 through a waveguide system, and may contribute to image generation. On the other hand, light deviating from the predetermined viewing angle, and may not reach the light coupling lenses 1200 and may be extinguished. According to some implementations, the light output (or light extraction efficiency) within the viewing angle that may contribute to the image generation may be increased, and a display apparatus 10 with a reduced viewing angle, thereby improving the image quality produced by the light coupling lenses 1200.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A display apparatus, comprising:
a circuit board including a driving circuit;
a pixel array disposed on the circuit board, the pixel array having a plurality of LED cells respectively including a first conductivity-type semiconductor layer, an active layer, and a second conductivity-type semiconductor layer sequentially stacked on the circuit board; and
microlenses arranged on the plurality of LED cells of the pixel array,
wherein the pixel array includes:
a reflective layer disposed between the plurality of LED cells and the microlenses, the reflective layer having a first surface facing the plurality of LED cells and a second surface facing the microlenses;
reflective electrodes covering at least a side surface of each of the plurality of LED cells;
a passivation layer between the plurality of LED cells and the reflective electrodes; and
bonding electrodes passing through the passivation layer and configured to electrically connect the first conductivity-type semiconductor layer and the second conductivity-type semiconductor layer to the driving circuit, and
wherein the reflective layer is configured to transmit light having an incidence angle equal to or less than a first angle among light incident on the first surface, and to reflect light having an incidence angle of a second angle that is greater than the first angle.

2. The display apparatus of claim 1, wherein the first angle is approximately 40° or less.

3. The display apparatus of claim 1, wherein light transmitted through the reflective layer has a predetermined refraction angle with respect to the second surface.

4. The display apparatus of claim 3, wherein the predetermined refraction angle is approximately 50° or less.

5. The display apparatus of claim 1, wherein the reflective layer includes two or more types of refractive films having different refractive indices that are stacked.

6. The display apparatus of claim 5, wherein the refractive films include at least one of silicon oxide, titanium oxide, aluminum oxide, zirconium oxide, and indium tin oxide.

7. The display apparatus of claim 1,
wherein the pixel array further includes a first conductive semiconductor base layer connected to the first conductive semiconductor layer of each of the plurality of LED cells, and lower reflective electrodes disposed between the plurality of LED cells and the bonding electrodes,
wherein the reflective electrodes extend through the passivation layer and electrically connect the bonding electrodes to the first conductive semiconductor base layer, and
wherein the lower reflective electrodes extend through the passivation layer and electrically connect the bonding electrodes to the second conductive semiconductor layer of each of the plurality of LED cells.

8. The display apparatus of claim 7, wherein the reflective electrodes are connected to the first conductive semiconductor base layer between the plurality of LED cells.

9. The display apparatus of claim 1,
wherein the pixel array includes a first conductive semiconductor base layer connected to the first conductive semiconductor layer of each of the plurality of LED cells, a transparent electrode layer on the first conductive semiconductor base layer, and a common electrode pad connected to the transparent electrode layer and the first conductive semiconductor base layer,
wherein the common electrode pad extends through the passivation layer and electrically connects the bonding electrodes to the first conductive semiconductor base layer, and
wherein each of the reflective electrodes extends through the passivation layer and electrically connects the bonding electrodes to the second conductive semiconductor layer of each of the plurality of LED cells.

10. The display apparatus of claim 9, wherein the reflective electrodes cover the side surface and a lower surface of each of the plurality of LED cells.

11. The display apparatus of claim 1,
wherein a first bonding electrode of the bonding electrodes connected to the second conductive semiconductor layer has a first height, and
a second bonding electrode of the bonding electrodes connected to the first conductive semiconductor layer has a second height greater than the first height.

12. A display apparatus, comprising:
a circuit board including a driving circuit;
a pixel array disposed on the circuit board, the pixel array having a plurality of LED cells respectively including a first conductivity-type semiconductor layer, an active layer, and a second conductivity-type semiconductor layer sequentially stacked on the circuit board; and
microlenses arranged on the plurality of LED cells,
wherein the pixel array includes:
a reflective layer disposed between the plurality of LED cells and the microlenses;
reflective electrodes covering at least a side surface of each of the plurality of LED cells;
a passivation layer between the plurality of LED cells and the reflective electrodes; and
bonding electrodes passing through the passivation layer and configured to electrically connect the first conductivity-type semiconductor layer and the second conductivity-type semiconductor layer to the driving circuit,
wherein the plurality of LED cells include a first LED cell configured to emit a first wavelength light, a second LED cell configured to emit a second wavelength light, longer than the first wavelength light, and a third LED cell configured to emit a third wavelength light longer than the second wavelength light, and
wherein the reflective layer transmits at least a portion of each of the first wavelength light, the second wavelength light, and the third wavelength light, and
wherein the reflective layer is configured to transmit the third wavelength light having a predetermined incidence angle, and to reflect the third wavelength light having an incidence angle greater than the predetermined incidence angle.

13. The display apparatus of claim 12,
wherein the first LED cell is configured to emit light having a wavelength of approximately 440 nm to approximately 480 nm,
wherein the second LED cell is configured to emit light having a wavelength of approximately 510 nm to approximately 550 nm, and
wherein the third LED cell is configured to emit light with a wavelength of approximately 610 nm to approximately 650 nm.

14. The display apparatus of claim 12, wherein the reflective layer comprises a Distributed Bragg Reflector (DBR) layer.

15. The display apparatus of claim 12, wherein respective intensities of the first wavelength light, the second wavelength light, and the third wavelength light, transmitted through the reflective layer, are stronger in a first region around a central axis, perpendicular to an upper surface of the reflective layer, than in a second region surrounding the first region.

16. The display apparatus of claim 15,
wherein the first region is a region from the central axis to a rotation angle ranging from approximately 15° to approximately 30°, and
wherein the second region is a region from an edge of the first region to the upper surface of the reflective layer.

17. The display apparatus of claim 16, wherein a first rotation angle defining the first region on the first LED cell, a second rotation angle defining the first region on the second LED cell, and a third rotation angle defining the first region on the third LED cell are different from each other.

18. A display apparatus, comprising:
a circuit board including a driving circuit;
a pixel array disposed on the circuit board, the pixel array having pixel units respectively formed of a plurality of subpixels; and
microlenses aligned on the plurality of subpixels,
wherein the pixel array includes:
a plurality of LED cells respectively corresponding to the plurality of subpixels and respectively including a first conductivity-type semiconductor layer, an active layer, and a second conductivity-type semiconductor layer;
a first conductive semiconductor base layer on the first conductive semiconductor layer of each of the plurality of LED cells;
a reflective layer between the first conductive semiconductor base layer and the microlenses;
reflective electrodes configured to cover a side surface and a lower surface of each of the plurality of LED cells; and
bonding electrodes configured to electrically connect the first conductivity-type semiconductor layer and the second conductivity-type semiconductor layer to the driving circuit, and
wherein the reflective layer is configured to transmit light having an incidence angle within a first angle, among light emitted from the plurality of LED cells, and to reflect light having an incidence angle of a second angle greater than the first angle.

19. The display apparatus of claim 18, wherein the first angle is approximately 40° or less.

20. The display apparatus of claim 18, wherein the light transmitted through the reflective layer has a refraction angle of approximately 50° or less.
